(19) United States
(12) Patent Application Publication
(10) Pub. No.: US 2023/0333334 A1
(43) Pub. Date: Oct. 19, 2023

(54) Photonic Integrated Circuit

(71) Applicant: Nippon Telegraph and Telephone Corporation, Tokyo (JP)

(72) Inventors: Yusuke Saito, Musashino-shi, Tokyo (JP); Yuta Ueda, Musashino-shi, Tokyo (JP); Mitsuteru Ishikawa, Musashino-shi, Tokyo (JP)

(21) Appl. No.: 18/001,658

(22) PCT Filed: Jun. 17, 2020
(86) PCT No.: PCT/JP2020/023778

§ 371 Date: Dec. 13, 2022

(51) Int. Cl. G02B 6/42

(52) U.S. Cl. CPC G02B 6/4251; G02B 6/4214; G02B 6/4283

(57) ABSTRACT

An photonic integrated circuit for which a mounting process in free space optics is not performed, formation and airtight sealing of an optical device are precisely performed, and cost reduction can be effectively achieved has a configuration including a lid portion connected to an upper surface of a semiconductor substrate to cover an optical waveguide and a mirror provided on the upper surface of the semiconductor substrate and a lens in the lid portion for concentrating light reflected by the mirror and emitting the light outward. A bonding material on an upper surface of a dielectric film formed above the upper surface of the semiconductor substrate and a bonding material formed in a peripheral edge portion of the lid portion are disposed so as to overlap witheach other to be bonded.

### TECHNICAL FIELD

The present disclosure relates to an photonic integrated circuit for high-speed communication formed on a substrate and including an optical waveguide and a lens.

### BACKGROUND ART

In the related art, a compound semiconductor used as a material for an optical device for high-speed communication is desired to have excellent properties such as a high optical gain and a high mobility. In an optical semiconductor device using such a compound semiconductor, a semiconductor chip is placed in a metal or ceramic package to be airtightly sealed, thereby ensuring stability of optical and electrical properties and long-term reliability.

The airtight sealing is performed because physical properties of the compound semiconductor of the optical semiconductor device are susceptible to moisture contained in a surrounding gas. For example, it is generally known that an end surface of a semiconductor laser, which is an example of the optical semiconductor device, deteriorates in reaction to moisture. In addition, when a humidity around a semiconductor waveguide of the optical semiconductor device changes, a stress applied to a semiconductor crystal changes, which affects a band gap or a refractive index. This changes oscillation wavelength in a semiconductor laser, for example.

In order to avoid such problems, in an optical semiconductor device in the related art, airtight sealing is typically performed using a package. However, although automation of mounting and sealing processes of such a package has progressed in recent years, there are actually many parts that are manually performed, which hinders reduction in work costs and material costs.

Thus, a structure has been investigated in which sealing is performed on an upper surface of a substrate constituting an photonic integrated circuit of the optical semiconductor device. Examples of a technique related to such a structure include an photonic integrated circuit for which airtight sealing can be performed locally in an inexpensive manner without a complex process (see PTL 1).

However, according to the photonic integrated circuit according to PTL 1, local airtight sealing is possible, but there still remains a mounting process in free space optics. Thus, there is a problem in that this mounting process prevents effective cost reduction.

In short, in the case of the photonic integrated circuit according to PTL 1, even if airtight sealing can be performed locally in an inexpensive manner on the upper surface of the substrate, the mounting process in the free space optics is implemented, so that effective cost reduction cannot be achieved.

### CITATION LIST

### Patent Literature

PTL 1: JP 2007-328201 A

### SUMMARY OF THE INVENTION

The present disclosure is intended to solve the above-described problems. An object of an embodiment according to the present disclosure is to provide an photonic integrated circuit for which a mounting process in free space optics is not implemented, formation and airtight sealing of an optical device are precisely performed, and cost reduction is effectively achieved.

In order to achieve the above-described object, an photonic integrated circuit according to an aspect of the present disclosure includes: an optical waveguide provided on an upper surface that is one main surface of a substrate; a mirror provided on the upper surface of the substrate and facing the optical waveguide, the mirror being configured to reflect light emitted from one end of the optical waveguide and emit the light in a direction perpendicular to the upper surface of the substrate; a lid portion provided to be connected to the upper surface of the substrate to cover the optical waveguide and the mirror and forming an airtightly sealed space between the lid portion and the upper surface of the substrate; and a lens provided in the lid portion at a location at which the light reflected by the mirror is capable of being emitted outward, the lens being configured to concentrate the light reflected by the mirror and emit the light outward.

According to the configuration of the aspect described above, the photonic integrated circuit has a configuration in which the lid portion is connected to the upper surface of the substrate so as to cover the optical waveguide and the mirror provided on the upper surface of the substrate, and the lens concentrating the light reflected by the mirror and emitting the concentrated light outward is provided in the lid portion. This makes it possible to form an airtightly sealed space in the lid portion between the lid portion and the upper surface of the substrate after the optical device is formed during manufacturing of the photonic integrated circuit, so that formation and airtight sealing of the optical device can be performed in a wafer stage of the substrate. As a result, without performing a mounting process in free space optics unlike PTL 1, an photonic integrated circuit in which formation and airtight sealing of an optical device are precisely achieved can be obtained, and cost reduction at the time of manufacturing the photonic integrated circuit can be effectively achieved.

### BRIEF DESCRIPTION OF DRAWINGS

FIG. 1 is a diagram illustrating a state of an initial manufacturing process of an photonic integrated circuit according to an embodiment of the present disclosure. FIG. 1(a) is a plan view of the photonic integrated circuit. FIG. 1(b) is a side cross-sectional view of the photonic integrated circuit taken along a Ib-Ib line in FIG. 1(a). FIG. 1(c) is a side cross-sectional view of the photonic integrated circuit taken along a Ic-Ic line in FIG. 1(a).

FIG. 2 is a diagram illustrating a state of an intermediate manufacturing process of the photonic integrated circuit according to the embodiment of the present disclosure. FIG. 2(a) is a plan view of the photonic integrated circuit. FIG. 2(b) is a side cross-sectional view of the photonic integrated circuit taken along a IIb-IIb line in FIG. 2(a). FIG. 2(c) is a side cross-sectional view of the photonic integrated circuit taken along a IIc-IIc line in FIG. 2(a).

FIG. 3 is a diagram illustrating a state of a later manufacturing process of the photonic integrated circuit according to the embodiment of the present disclosure. FIG. 3(a) is a plan view of the photonic integrated circuit. FIG. 3(b) is a side cross-sectional view of the photonic integrated circuit taken along a IIIb-IIIb line in FIG. 3(a). FIG. 3(c) is a side cross-sectional view of the photonic integrated circuit taken along a IIIc-IIIc line in FIG. 3(a).

FIG. 4 is a diagram illustrating a state of a final manufacturing process of the photonic integrated circuit according to the embodiment of the present disclosure. FIG. 4(a) is a plan view of the photonic integrated circuit. FIG. 4(b) is a side cross-sectional view of the photonic integrated circuit taken along a IVb-IVb line in FIG. 4(a).

### DESCRIPTION OF EMBODIMENTS

Hereinafter, an photonic integrated circuit according to an embodiment of the present disclosure will be described in detail with reference to the drawings.

### Embodiments

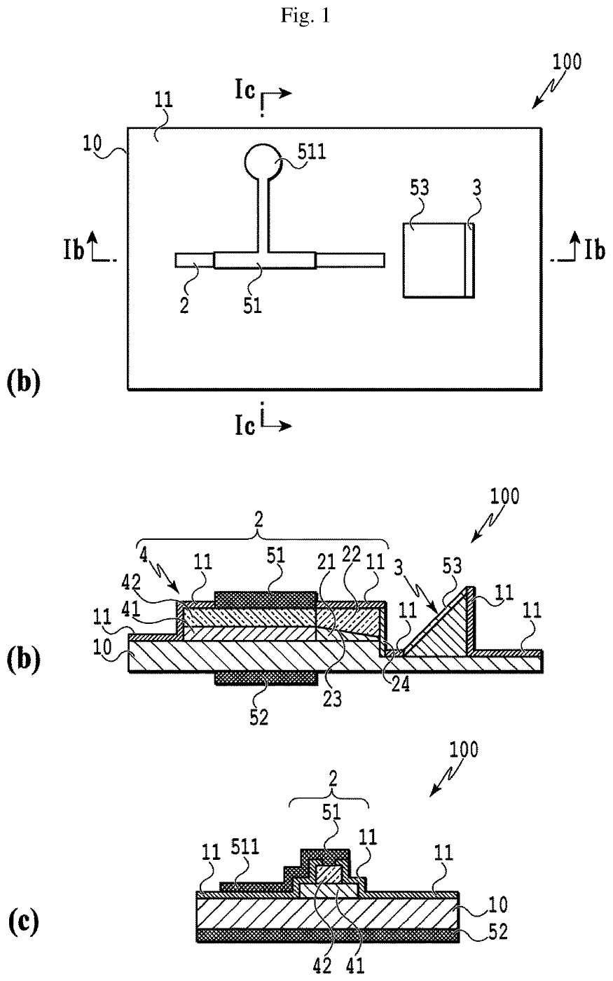

FIG. 1 is a diagram illustrating a state of an initial manufacturing process of an photonic integrated circuit 100 according to an embodiment of the present disclosure. FIG. 1(a) is a plan view of the photonic integrated circuit 100. FIG. 1(b) is a side cross-sectional view of the photonic integrated circuit 100 taken along a Ib-Ib line in FIG. 1(a). FIG. 1(c) is a side cross-sectional view of the photonic integrated circuit 100 taken along a Ic-Ic line in FIG. 1(a).

With reference to FIG. 1(a), in the initial manufacturing process of the photonic integrated circuit 100, an optical waveguide 2 and a mirror 3 are formed on an upper surface that is one main surface of a semiconductor substrate 10 in a wafer state (hereinafter, referred to simply as the upper surface). A dielectric film 11 is formed in an upper portion of the semiconductor substrate 10 including optical devices such as the optical waveguide 2 and the mirror 3. FIG. 1(a) illustrates a metal film 53 provided on an inclined surface of the mirror 3, a surface electrode 51 included in the optical waveguide 2, and a lead-out electrode 511 provided at an end portion continuously extending from the surface electrode 51.

With reference to FIG. 1(b), the optical waveguide 2 includes a core layer 21 and a cladding layer 22 provided in a specific region on the upper surface of the semiconductor substrate 10, and an active region 41 and a cladding layer 42 provided in another region adjacent to the specific region. The active region 41 and the cladding layer 42 constitute a laser 4 as a light emitting source. The surface electrode 51 described above is formed in a region including an upper portion of the laser 4 and an upper portion of the optical waveguide 2. In addition, a rear surface electrode 52 is provided on a lower surface that is the other main surface of the semiconductor substrate 10 in a region opposite to the surface electrode 51 of the optical waveguide 2.

Furthermore, the optical waveguide 2 includes a tapered portion 23 that has an inclined surface inclined downward toward the upper surface of the semiconductor substrate 10 to continuously change a thickness of a core layer 21. The tapered portion 23 is processed in such a manner that the thickness of the core layer 21 gradually decreases toward one end serving as an emission end of the optical waveguide 2. Note that the thickness of the core layer 21 here indicates a dimension of the core layer 21 in a direction perpendicular to a plane of the semiconductor substrate 10. Note that while the structure for continuously decreasing the thickness of the core layer 21 is an example, other structures may be applied, such as a structure in which the thickness of the core layer 21 is decreased in a stepwise manner, for example. Various techniques such as dry etching or wet etching can be applied to the processing.

In addition, a non-reflective coating film 24 is formed at the one end of the optical waveguide 2 on a wall surface of a recessed portion formed for forming the mirror 3 of the semiconductor substrate 10. The metal film 53 is formed on the inclined surface of the mirror 3 provided facing the optical waveguide 2, the inclined surface being inclined upward toward the upper surface of the semiconductor substrate 10. The non-reflective coating film 24 is a dielectric film that can be formed by a method such as plasma chemical vapor deposition (CVD) or sputtering, and can be formed from various materials. The mirror 3 can be formed by selective regrowth by metal organic chemical vapor deposition (MOCVD), or various types of etching. Note that in a case of employing the MOCVD, the mirror 3 can be formed simultaneously with the cladding layer 22 or the cladding layer 42.

With reference to FIG. 1(c), the surface electrode 51 is formed to be electrically connected to the cladding layer 42, and the lead-out electrode 511 is formed on the upper surface of the dielectric film 11. The surface electrode 51 and the lead-out electrode 511 are formed by a method such as vapor deposition. The surface electrode 51, the lead-out electrode 511, and the metal film 53 can be formed simultaneously. The dielectric film 11 is formed in the upper portion of the semiconductor substrate 10 including the optical waveguide 2, the mirror 3, and the laser 4 by a method such as plasma CVD. For a material of the dielectric film 11, silicic acid, silicon nitride, silicon oxynitride, or the like is suitable.

Note that for a material of the semiconductor substrate 10 described above, n-type-doped InP is suitable. For the core layer 21 and the active region 41, a mixed crystal including a plurality of Group III to V materials such as In, Ga, As, P, or Al is suitable. Furthermore, for the cladding layer 22 and the cladding layer 42, p-type-doped InP is suitable. However, as long as a compound semiconductor material is capable of forming an optical waveguide structure, any material may be used. In particular, for the cladding layer 22, a material need not necessarily be doped. In addition, for the semiconductor substrate 10 and the cladding layer 42, the doped type may be reversed. The optical waveguide 2 and the laser 4 are formed by a combination of a crystal growth method such as MOCVD or molecular beam epitaxy (MBE) and a method such as dry etching or wet etching. Various methods such as dry etching or wet etching can be applied to the processing described above.

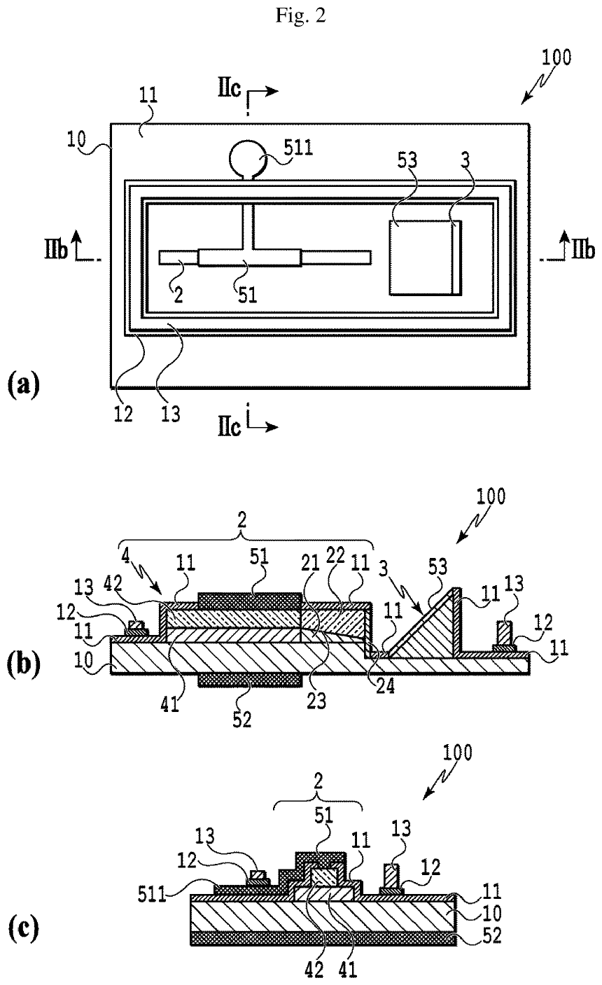

FIG. 2 is a diagram illustrating a state of an intermediate manufacturing process of the photonic integrated circuit 100 according to the embodiment of the present disclosure. FIG. 2(a) is a plan view of the photonic integrated circuit 100. FIG. 2(b) is a side cross-sectional view of the photonic integrated circuit 100 taken along a IIb-IIb line in FIG. 2(a). FIG. 2(c) is a side cross-sectional view of the photonic integrated circuit 100 taken along a IIc-IIc line in FIG. 2(a).

With reference to FIG. 2(a), in the intermediate manufacturing process of the photonic integrated circuit 100, a dielectric film 12 is formed above the upper surface of the semiconductor substrate 10 in a wafer state so as to surround the optical waveguide 2 and the mirror 3 and traverse the lead-out electrode 511. The dielectric film 12 is formed above the entire upper surface of the semiconductor substrate 10 by plasma CVD or the like, and then a frame-like location to be left is masked to surround the optical waveguide 2 and the mirror 3 and dry etching is performed, so that the dielectric film 12 is formed into a desired shape. Note that the dielectric film 12 is also partially formed on an upper surface of the lead-out electrode 511. As a material of the dielectric film 12, it is desirable to use silicic acid, silicon nitride, silicon oxynitride, or the like. Then, a bonding member 13 is formed on an upper surface of the dielectric film 12. As a material of the bonding member 13, a solder, an Au bump, or the like is suitable. The bonding member 13 is formed by a method such as vapor deposition, for example.

With reference to FIG. 2(b), it can be seen that the dielectric film 12 and a bonding material 13 are formed above the upper surface of the semiconductor substrate 10 outside a portion where the optical waveguide 2 and the mirror 3 are provided. Other details are as described with reference to FIG. 1(b).

With reference to FIG. 2(c), it can be seen that the dielectric film 12 and the bonding material 13 are also formed on the upper surface of the lead-out electrode 511 in addition to the upper surface of the dielectric film 11. According to this structure, the lead-out electrode 511 and the bonding material 13 are insulated from each other, and even after airtight sealing is performed, it is possible to supply power to the laser 4 from the lead-out electrode 511 and the rear surface electrode 52.

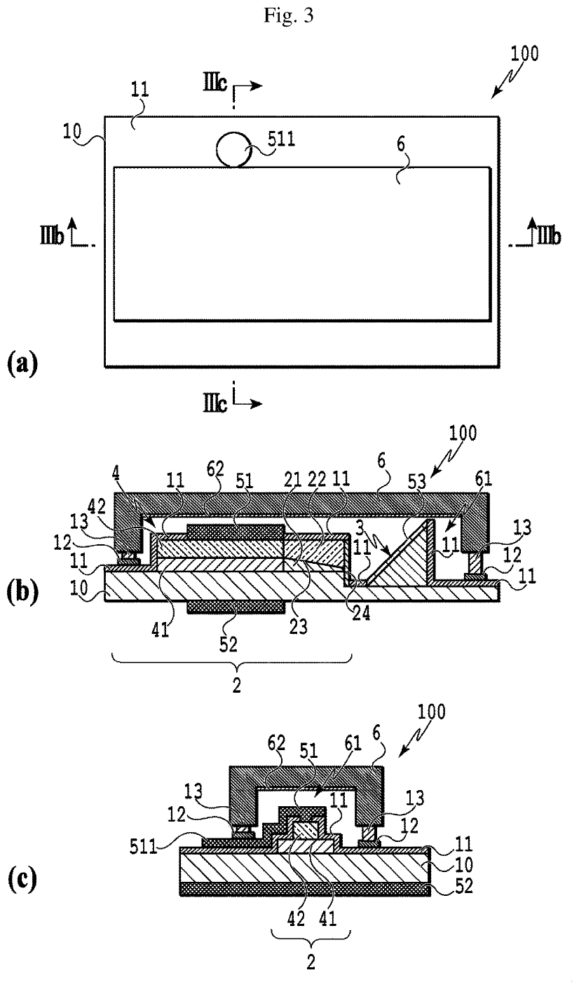

FIG. 3 is a diagram illustrating a state of a later manufacturing process of the photonic integrated circuit 100 according to the embodiment of the present disclosure. FIG. 3(a) is a plan view of the photonic integrated circuit 100. FIG. 3(b) is a side cross-sectional view of the photonic integrated circuit 100 taken along a IIIb-IIIb line in FIG. 3(a). FIG. 3(c) is a side cross-sectional view of the photonic integrated circuit 100 taken along a IIIc-IIIc line in FIG. 3(a).

With reference to FIG. 3(a), in the later manufacturing process of the photonic integrated circuit 100, a lid portion 6 is bonded to surround the optical waveguide 2 and the mirror 3, and cover a region traversing a lead portion of the lead-out electrode 511 above the upper surface of the semiconductor substrate 10 in the wafer state. The lid portion 6 is used to perform airtight sealing of the optical devices. It is desirable to use the same material as the semiconductor substrate 10 for a material of the lid portion 6 from the perspective of consistency of a thermal expansion coefficient. In addition, for the material of the lid portion 6, it is desirable to use a material having at least a refractive index similar to that of the semiconductor substrate 10 from the perspective of producing a lens 7 described below. As an example, InP is suitable for the material of the lid portion 6. As another material, Si may be used for the material of the lid portion 6.

With reference to FIG. 3(b) and FIG. 3(c), a groove 61 for accommodating the optical devices is formed on an inner surface of the lid portion 6, and a non-reflective coating film 62 is further formed at a portion of an inner surface of the groove 61 that faces the upper surface of the semiconductor substrate 10.

In order to produce the lid portion 6 capable of airtight sealing, the groove 61 is first formed in a material block of the lid portion 6 by dry etching or wet etching to form a box-shaped body. Thereafter, the non-reflective coating film 62 is formed on the groove 61 on a box-shaped inner surface by CVD or the like. Next, the bonding material 13 is formed by a method such as vapor deposition on a peripheral edge portion of the box-shaped lid portion 6. The peripheral edge portion corresponds to a portion other than a portion where the groove 61 is formed. Then, the bonding material 13 on the upper surface of the dielectric film 12 formed above the upper surface of the semiconductor substrate 10 and the bonding material 13 formed on the peripheral edge portion of the lid portion 6 are disposed so as to overlap witheach other, and both the bonding materials 13 are bonded to each other in an inert gas or vacuum.

In the bonding process, when bonding is promoted, ultrasonic waves or a technique such as pressing or heating is applied to the semiconductor substrate 10 and the lid portion 6. When bonding is not promoted, the semiconductor substrate 10 and the lid portion 6 are merely placed still. According to the bonding process, a space between the upper surface of the semiconductor substrate 10 and the inner side of the lid portion 6 (the side on which the non-reflective coating film 62 is formed) is airtightly sealed.

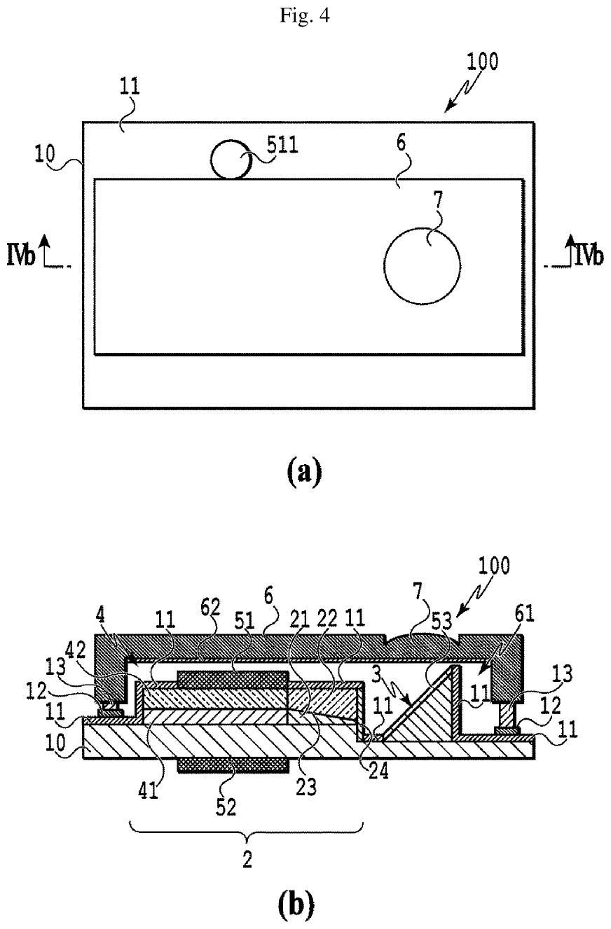

FIG. 4 is a diagram illustrating a state of a final manufacturing process of the photonic integrated circuit 100 according to the embodiment of the present disclosure. FIG. 4(a) is a plan view of the photonic integrated circuit 100. FIG. 4(b) is a side cross-sectional view illustrating the photonic integrated circuit taken along a IVb-IVb line in FIG. 4(a).

With reference to FIG. 4(a), in the final manufacturing process of the photonic integrated circuit 100, the lens 7 is formed in the lid portion 6 bonded to the upper surface of the semiconductor substrate 100 in the wafer state at a location where light reflected by the mirror 3 can be emitted outward. The lens 7 is responsible for concentrating and collimating the light reflected by the mirror and emitting the light outward.

FIG. 4(b) is a cross-sectional view taken along a IVb-IVb line in FIG. 4(a). In order to form the lens 7, the following procedure is adopted: a mark is made in the semiconductor substrate 10 in advance by photolithography and etching, alignment is performed in accordance with the mark, and photolithography and etching are performed on the lid portion 6. In this way, it is possible to precisely produce the lens 7 at a position where light reflected by the mirror 3 is emitted. At this time, when a material having a low refractive index is used as the material of the lid portion 6, a curvature for concentrating light increases, which makes it difficult to produce the lens 7, and thus, a material having a high refractive index to some extent is used. As a result, as described above, a material having a refractive index as high as that of the semiconductor substrate 10 is used as the material of the lid portion 6.

In this way, the photonic integrated circuit 100 produced on the upper surface of the semiconductor substrate 100 in the wafer state is typically produced in a large number of lots, and is then cut out to be products. In any way, in the produced photonic integrated circuit 100, a laser light generated by the laser 4 can be emitted to a free space that is airtightly sealed through the non-reflective coating film 24 at an end surface of the optical waveguide 2 including the tapered portion 23 of the core layer 21. The laser light emitted to the free space can be then reflected vertically with respect to the upper surface of the semiconductor substrate 10 by the metal film 53 provided on the inclined surface of the mirror 3. Furthermore, the laser light reflected by the metal film 53 of the mirror 3 can be concentrated and collimated by the lens 7 provided in the lid portion 6 to be emitted outward.

When a structural technical outline is described for the photonic integrated circuit 100 described above, it has a configuration in which the lid portion 6 is connected to the upper surface of the semiconductor substrate 100 so as to cover the optical waveguide 2 and the mirror 3 provided on the upper surface of the semiconductor substrate 100. This makes it possible to form an airtightly sealed space between the lid portion 6 and the upper surface of the semiconductor substrate 100. Furthermore, the photonic integrated circuit 100 has a configuration in which the lid portion 6 is provided with the lens 7 concentrating the light reflected by the mirror 3 and emitting the light outward. As a result, it is possible to concentrate and collimate the light reflected by the mirror 3 by the lens 7 and emit the light outward.

Of these elements, the mirror 3 is provided facing the optical waveguide 2 on the upper surface of the semiconductor substrate 100, reflects light emitted from one end of the optical waveguide 2, and emits the light in the perpendicular direction with respect to the upper surface of the semiconductor substrate 10. The lid portion 6 is connected to the upper surface of the semiconductor substrate 100 so as to cover the optical waveguide 2 and the mirror 3, thereby forming an airtightly sealed space between the lid portion 6 and the upper surface of the semiconductor substrate 100. The lens 7 is provided in the lid portion 6 at a location where the light reflected by the mirror 3 can be emitted outward.

According to the photonic integrated circuit 100 having such a configuration, an airtightly sealed space is formed between the lid portion 6 and the upper surface of the semiconductor substrate 100 after the optical devices are formed during manufacture, so that formation and airtight sealing of the optical devices can be performed in the wafer stage of the semiconductor substrate 100. As a result, without performing the mounting process in the free space optics as in PTL 1, the photonic integrated circuit 100 in which formation and airtight sealing of the optical devices have been precisely performed is obtained. Thus, cost reduction at the time of manufacturing the photonic integrated circuit 100 can be effectively achieved.

1. An photonic integrated circuit comprising:
an optical waveguide provided on an upper surface that is one main surface of a substrate;
a mirror provided on the upper surface of the substrate and facing the optical waveguide, the mirror being configured to reflect light emitted from one end of the optical waveguide and emit the light in a direction perpendicular to the upper surface of the substrate;
a lid portion provided to be connected to the upper surface of the substrate to cover the optical waveguide and the mirror and forming an airtightly sealed space between the lid portion and the upper surface of the substrate; and
a lens provided in the lid portion at a location at which the light reflected by the mirror is capable of being emitted outward, the lens being configured to concentrate the light reflected by the mirror and emit the light outward.

2. The photonic integrated circuit according to claim 1, wherein
the optical waveguide comprises a laser as a light-emitting source including an active region and a cladding layer provided on the upper surface of the substrate.

3. The photonic integrated circuit according to claim 2, wherein
the optical waveguide comprises a tapered portion processed such that a thickness of a core layer provided on the upper surface of the substrate gradually decreases toward one end serving as an emission end.

4. The photonic integrated circuit according to claim 1, wherein
a material having at least a refractive index as high as a refractive index of the substrate is used for the lid portion to form the lens.

5. The photonic integrated circuit according to claim 1, wherein
the airtightly sealed space is filled with inert gas.

6. The photonic integrated circuit according to claim 1, wherein
the airtightly sealed space is a vacuum.
